(19) United States
(12) Patent Application Publication
(10) Pub. No.: US 2009/0256151 A1
(43) Pub. Date: Oct. 15, 2009

(54) DISPLAY SUBSTRATE AND METHOD OF MANUFACTURING THE SAME

(76) Inventors: Jong-Moo Huh, Hwaseong-si (KR); Joon-Hoo Choi, Seoul (KR)

Correspondence Address: Haynes and Boone, LLP;IP Section, 2323 Victory Avenue, SUITE 700, Dallas, TX, 75219, US

(21) Appl. No.: 12/345,029

(22) Filed: Dec. 29, 2008

(30) Foreign Application Priority Data
Apr. 11, 2008 (KR) 2008-0033837

(51) Int. Cl. H01L 29/78; H01L 29/04; H01L 21/31; H01L 21/22

(52) U.S. Cl. 257/59; 257/288; 438/482; 438/197; 257/E29.255; 257/E29.003; 257/E21.09

(57) ABSTRACT

A display substrate comprises a substrate; a source electrode arranged on the substrate; a drain electrode arranged on the substrate and spaced from the source electrode; a semiconductor layer arranged on the source electrode and the drain electrode; an insulating layer arranged on the semiconductor layer; and a gate electrode arranged on the insulating layer, wherein the semiconductor layer comprises: a first ohmic contact region that overlays an upper surface and a side surface of the source electrode; a second ohmic contact region that overlays an upper surface and a side surface of the drain electrode; and a channel region that is spaced from the source and drain electrodes and interconnects the first ohmic contact region and the second ohmic contact region.

### CROSS-REFERENCE TO RELATED APPLICATION

This application relies for priority upon South Korean Patent Application No. 2008-33837 filed on Apr. 11, 2008, the contents of which are herein incorporated by reference in its entirety.

### BACKGROUND

1. Field of the Invention

The present invention relates to display substrates.

2. Description of the Related Art

A typical flat panel display includes a thin film transistor substrate with thin film transistors serving as switching devices. The transistors' channel regions can be formed from a number of semiconductor materials such as polysilicon, amorphous silicon, or microcrystalline silicon. Microcrystalline silicon has similar properties to polysilicon and is formed by similar methods but not including a separate crystallization process.

To fabricate the thin film transistors, a microcrystalline silicon layer can be deposited and patterned to form the transistors' channel regions, and then another conductive layer can be deposited and patterned into the source and drain regions. When the source and drain regions are being patterned, the microcrystalline silicon layer may be detached due to the process stress. Also, the etch used to pattern the source and drain regions may attack the microcrystalline silicon layer and cause degradation of the thin film transistors' properties. Further, depending on an etch stop used in patterning the microcrystalline silicon layer, additional process changes may be required and may cause defects in the microcrystalline silicon.

### SUMMARY

Some embodiments of the present invention provide display substrates with improved operational characteristics and also provide display substrate manufacturing methods.

Some embodiments provide a display substrate including: a substrate; a source electrode arranged on the substrate; a drain electrode arranged on the substrate and spaced from the source electrode; a semiconductor layer arranged on the source electrode and the drain electrode; an insulating layer arranged on the semiconductor layer; and a gate electrode arranged on the insulating layer, wherein the semiconductor layer includes: a first ohmic contact region that overlays an upper surface and a side surface of the source electrode; a second ohmic contact region that overlays an upper surface and a side surface of the drain electrode; and a channel region that is spaced from the source and drain electrodes and interconnects the first ohmic contact region and the second ohmic contact region.

The channel region may be arranged on the substrate's portion not covered by the first and second ohmic contact regions.

Peripheral areas of the first ohmic contact region may cover areas of the substrate adjacent to the source electrode, and peripheral areas of the second ohmic contact region may cover areas of the substrate adjacent to the drain electrode. The semiconductor layer may include at least one of microcrystalline silicon, amorphous silicon and polysilicon.

Some embodiments provide a display substrate including: a substrate; a gate electrode arranged on the substrate; an insulating layer arranged on the substrate over the gate electrode; a source electrode arranged on the insulating layer; a drain electrode arranged on the insulating layer and spaced from the source electrode; and a semiconductor layer arranged on the source electrode and the drain electrode, wherein the semiconductor layer includes: a first ohmic contact region that overlays an upper surface and a side surface of the source electrode; a second ohmic contact region that overlays an upper surface and a side surface of the drain electrode; and a channel region that is spaced from the source and drain electrodes and interconnects the first ohmic contact region and the second ohmic contact region.

The channel region may be arranged on the substrate's portion not covered by the first and second ohmic contact regions.

Some embodiments provide a method of manufacturing a display substrate, the method including: forming, on a substrate, a source electrode and a drain electrode spaced from the source electrode; depositing a semiconductor material on the substrate, the source electrode and the drain electrode to form a semiconductor layer including a first ohmic contact region that overlays an upper surface and a side surface of the source electrode, a second ohmic contact region that overlays an upper surface and a side surface of the drain electrode, and a channel region that is spaced from the source and drain electrodes and overlays the substrate's portion between the first ohmic contact region and the second ohmic contact region; forming an insulating layer on the semiconductor layer; forming a gate electrode on the insulating layer; and forming a protective layer on the gate electrode and the insulating layer.

In order to form the semiconductor layer, the semiconductor material may be deposited on the substrate, the source electrode and the drain electrode, and may be doped to define the first ohmic contact region, the second ohmic contact region and the channel region; and the semiconductor material may be removed from areas which do not contain the first ohmic contact region, the second ohmic contact region and the channel region. The semiconductor material may be doped by ion implantation, e.g. ion shower.

In some embodiments, in order to form the semiconductor layer, the semiconductor material may be deposited on the substrate, the source electrode and the drain electrode, and may be etched to form the semiconductor layer that overlays upper and side surfaces of each of the source and drain electrodes and overlays the substrate between the source electrode and the drain electrode; and the semiconductor layer may be doped to define the first ohmic contact region, the second ohmic contact region and the channel region.

The semiconductor layer may be doped by ion implantation. The semiconductor material may be deposited by chemical vapor deposition and include at least one of microcrystalline silicon and amorphous silicon.

After forming the protective layer, the protective layer and the insulating layer may be etched to form a contact hole that partially exposes the drain electrode; and a pixel electrode may be formed to be electrically connected to the drain electrode through the contact hole.

In addition, a buffer layer may be formed on the substrate prior to forming the source and drain electrodes.

Some embodiments of the present invention provide a method of manufacturing a display substrate, the method including: forming a gate electrode on a substrate; forming an insulating layer on the substrate over the gate electrode; forming, on the insulating layer, a source electrode and a drain electrode spaced from the source electrode; forming a semiconductor layer on the insulating layer, the source electrode and the drain electrode, the semiconductor layer including a first ohmic contact region that overlays an upper surface and a side surface of the source electrode, a second ohmic contact region that overlays an upper surface and a side surface of the drain electrode, and a channel region that is spaced from the source and drain electrodes and overlays the substrate's portion between the first ohmic contact region and the second ohmic contact region; and forming a protective layer on the semiconductor layer.

Forming the semiconductor layer may include: depositing a semiconductor material on the insulating layer, the source electrode and the drain electrode; doping the semiconductor material to define the first ohmic contact region, the second ohmic contact region, and the channel region; and removing the semiconductor material from areas which do not contain the first ohmic contact region, the second ohmic contact region and the channel region.

The semiconductor material may be performed by ion implantation method.

Forming the semiconductor layer may include depositing a semiconductor material on the insulating layer, the source electrode and the drain electrode; etching the semiconductor material to form the semiconductor layer that overlays upper surfaces and side surfaces of the source and drain electrodes; and doping the semiconductor layer to define the first ohmic contact region, the second ohmic contact region and the channel region.

According to the above, the ohmic contact regions overlie the source and drain electrodes in top-gate and bottom-gate structures. The channel region is spaced from the source and drain electrodes, thereby reducing current leakage.

### BRIEF DESCRIPTION OF THE DRAWINGS

FIG. 1 shows a vertical cross section of a display substrate according to some embodiments of the present invention;

FIG. 2 shows a vertical cross section of a display substrate according to some other embodiments of the present invention;

FIG. 3 is a flowchart illustrating a method of manufacturing a display substrate according to some embodiments of the present invention;

FIGS. 4A to 4E show vertical cross sections of a display substrate at different stages of fabrication by the method of FIG. 3;

FIG. 5 is a flowchart illustrating another method of manufacturing a display substrate according to some embodiments of the present invention; and

FIGS. 6A to 6D show vertical cross sections of a display substrate at different stages of fabrication by the method of FIG. 5.

### DESCRIPTION OF SOME EMBODIMENTS

The embodiments described in this section illustrate but do not limit the invention. The invention is defined by the appended claims.

It will be understood that when an element or layer is referred to as being “on”, “connected to” or “coupled to” another element or layer, then intervening elements or layers may or may not be present. In contrast, when an element or layer is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

Terms like “first”, “second”, etc. may be used herein as reference labels to describe various elements, components, regions, layers and/or sections. These labels are interchangeable and do not limit the invention.

Spatially relative terms such as “beneath”, “below”, “lower”, “above”, “upper” and the like, may be used herein to describe one element or feature's relationship to another element(s) or feature(s) as illustrated in the figures. The spatially relative terms do not limit the invention to the orientation depicted in the figures. For example, if a device in the figures is turned over, elements described as “below” or “beneath” other elements or features would then be oriented “above” the other elements or features. Devices may be otherwise oriented (e.g. rotated 90 degrees or by other angles).

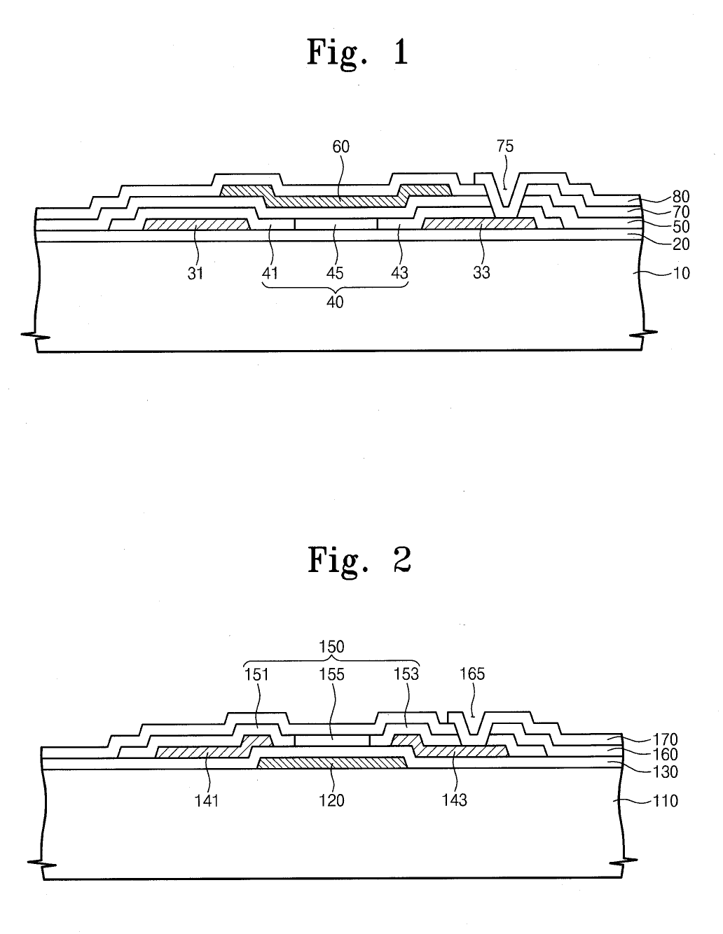

FIG. 1 shows a vertical cross section of a display substrate according to an exemplary embodiment of the present invention. The display substrate includes a substrate 10, a buffer layer 20, source electrodes 31, drain electrodes 33, a semiconductor layer 40, an insulating layer 50, gate electrodes 60, a protective layer 70, and pixel electrodes 80. Each pixel may include a source electrode 31, a drain electrode 33, a gate electrode 60, and a pixel electrode 80.

The substrate 10 includes glass or plastic and is substantially flat.

The buffer layer 20 is arranged on the substrate 10. The buffer layer 20 may include various materials such as silicon nitride (SiNx), silicon oxide (SiOx), silicon oxynitride (SiOxNx) or the like. Such buffer layer 20 may protect channel regions 45 of the semiconductor layer 40 from being contaminated by impurities in the substrate 10.

The source electrodes 31 and the drain electrodes 33 are formed by depositing a suitable metal (“source/drain metal” below) on the buffer layer 20 and patterning the source/drain metal. In each pixel, the source and drain electrodes 31 and 33 are spaced from each other by a predetermined distance.

The semiconductor layer 40 is formed over the source electrodes 31 and the drain electrodes 33. In each pixel, the semiconductor layer 40 overlies the buffer layer 20 between the source and drain electrodes 31 and 33. The semiconductor layer 40 may include any one of microcrystalline silicon, polysilicon, and amorphous silicon. In each pixel, the semiconductor layer 40 is divided into a first ohmic contact region 41, a second ohmic contact region 43, and the channel region 45.

In each pixel, the first ohmic contact region 41 overlays an upper surface and a side surface of the source electrode 31. Peripheral areas of the first ohmic contact region 41 overlie portions of the buffer layer 20 adjacent to the source electrode 31. In some embodiments, the peripheral areas of the first ohmic contact region 41 extend beyond the source electrode 31 by about 1 micrometer to about 10 micrometers. If the peripheral areas are drawn to be narrower than 1 micrometer, then it is possible (due to a mask misalignment) for the first ohmic contact region 41 to terminate over the top or side surface of the source electrode 31, and if the peripheral areas are wider than 10 micrometers, the resistance of the ohmic contact region 41 may become undesirably large. The first ohmic contact region 41 is doped by impurity implantation. For instance, the first ohmic contact region 41 may be formed from microcrystalline silicon doped by impurities such as phosphorous (P), boron (B), or the like. The impurities may be introduced by ion implantation, e.g. by an ion shower method.

In each pixel, the second ohmic contact region 43 overlays an upper surface and a side surface of the drain electrode 33 and includes peripheral areas covering portions of the buffer layer 20 adjacent to the drain electrode 33. Similar to the first ohmic contact region 41, the peripheral areas of the second ohmic contact region 43 may have a width of about 1 micrometer to about 10 micrometers. The second ohmic contact region 43 may be doped by impurities simultaneously with the first ohmic contact region 41.

The first ohmic contact region 41 reduces the contact resistance between the source electrode 31 and the channel region 45, and the second ohmic contact region 43 reduces the contact resistance between the drain electrode 33 and the channel region 45. The source and drain electrodes 31 and 33 are spaced from the channel region 45 and are separated from the channel region 45 by the first and second ohmic contact regions 41 and 43, respectively, and this separation reduces the leakage current between the source and drain electrodes 31 and 33 through the channel region 45. Of note, the first and second ohmic contact regions 41 and 43 may be treated by heat or hydrogen plasma to acquire a stable crystalline structure.

In each pixel, the channel region 45 is positioned between the first ohmic contact region 41 and the second ohmic region 43. The channel region 45 overlies the buffer layer 20 between the source electrode 31 and the drain electrode 33. The channel region 45 provides a current path between the source electrode 31 and the drain electrode 33.

The insulating layer 50 is formed on the buffer layer 20 and the semiconductor layer 40 and includes, for example, an insulating material such as silicon oxide (SiOx) or silicon nitride (SiNx).

The gate electrodes 60 are formed on the insulating layer 50 by depositing a suitable metal (“gate metal” below) on the insulating layer 50 and patterning the gate metal. As shown in FIG. 1, in each pixel the gate electrode 60 overlies the channel region 45.

The protective layer 70 is formed on the insulating layer 50 and the gate electrode 60 and includes an insulating material such as silicon oxide (SiOx), silicon nitride (SiNx) or the like.

The pixel electrodes 80 are formed on the protective layer 70 and include a conductive material such as indium tin oxide (ITO), tin oxide (TO), indium zinc oxide (IZO), etc. In each pixel, the pixel electrode 80 is electrically connected with the drain electrode 33 through a contact hole 75 formed through the protective layer 70, the insulating layer 50 and the second ohmic contact region 43.

FIG. 2 shows a vertical cross section of a display substrate according to another exemplary embodiment of the present invention. This display substrate includes a substrate 110, gate electrodes 120, an insulating layer 130, source electrodes 141, drain electrodes 143, a semiconductor layer 150, a protective layer 160, and pixel electrodes 170. Each pixel may include a gate electrode 120, a source electrode 141, a drain electrode 143, and a pixel electrode 170.

The substrate 110 includes glass or plastic and is substantially flat.

The gate electrodes 120 are formed on the substrate 110 by depositing a gate metal on the substrate 110 and patterning the gate metal.

The insulating layer 130 is formed on the substrate 110 and the gate electrodes 120.

The source electrodes 141 and the drain electrodes 143 are formed by depositing a source/drain metal on the insulating layer 130 and patterning the source/drain metal. In each pixel, the source and drain electrodes 141 and 143 are spaced from each other by a predetermined distance.

The semiconductor layer 150 is formed over the insulating layer 130, the source electrodes 141 and the drain electrodes 143. The semiconductor layer 150 may include any one of microcrystalline silicon, polysilicon, and amorphous silicon. In each pixel, the semiconductor layer 150 is divided into a first ohmic contact region 151, a second ohmic contact region 153, and a channel region 155.

In each pixel, the first ohmic contact region 151 overlays an upper surface and a side surface of the source electrode 141. Peripheral areas of the first ohmic contact region 151 cover portions of the insulating layer 130 adjacent to the source electrode 141. The first ohmic contact region 151 is formed by impurities implantation, possibly by ion implantation, e.g. by ion shower.

The second ohmic contact region 153 overlays an upper surface and a side surface of the drain electrode 143. Peripheral areas of the second ohmic contact region 153 cover portions of the insulating layer 130 adjacent to the drain electrode 143. The second ohmic contact region 153 may be formed by impurities implantation simultaneously with the first ohmic contact region 151.

In each pixel, the channel region 155 is positioned between the first ohmic contact region 151 and the second ohmic contact region 153. The channel region 155 is spaced from the source electrode 141 and the drain electrode 143. The channel region 155 overlies the insulating layer 130 between the source electrode 141 and the drain electrode 143. The channel region 155 provides a current path between the source electrode 141 and the drain electrode 143.

The protective layer 160 is formed on the insulating layer 130 and the semiconductor layer 150 and includes an insulating material such as silicon oxide (SiOx), silicon nitride (SiNx) or the like.

The pixel electrodes 170 are formed on the protective layer 160 and include a conductive material such as indium tin oxide (ITO), tin oxide (TO), indium zinc oxide (IZO), etc. In each pixel, the pixel electrode 170 is electrically connected with the drain electrode 143 through a contact hole 165 formed through the protective layer 160 and the second ohmic contact region 153.

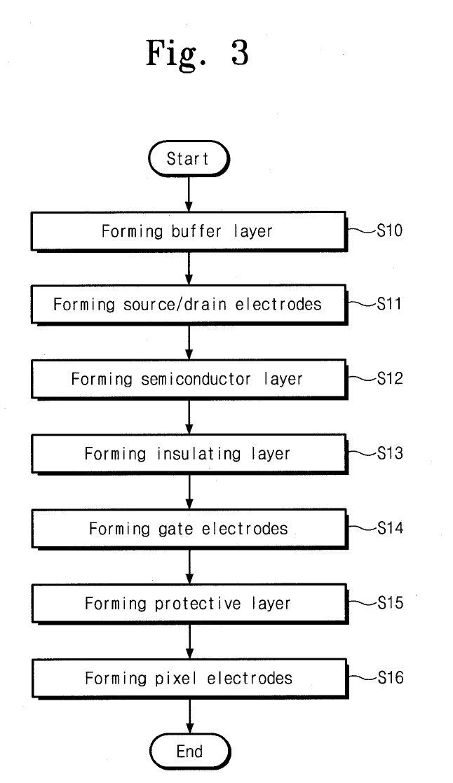

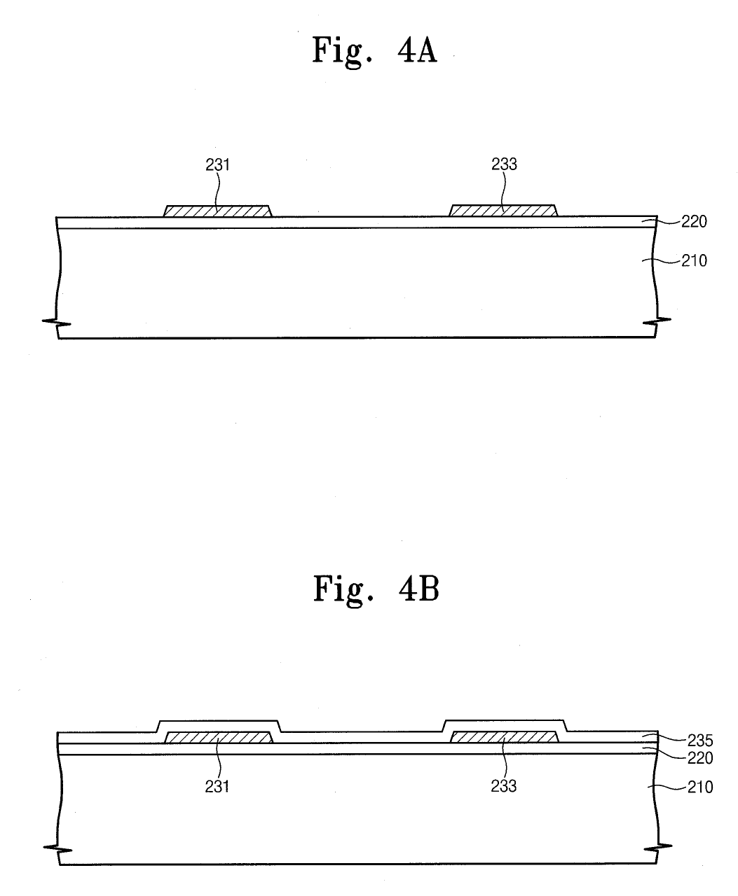

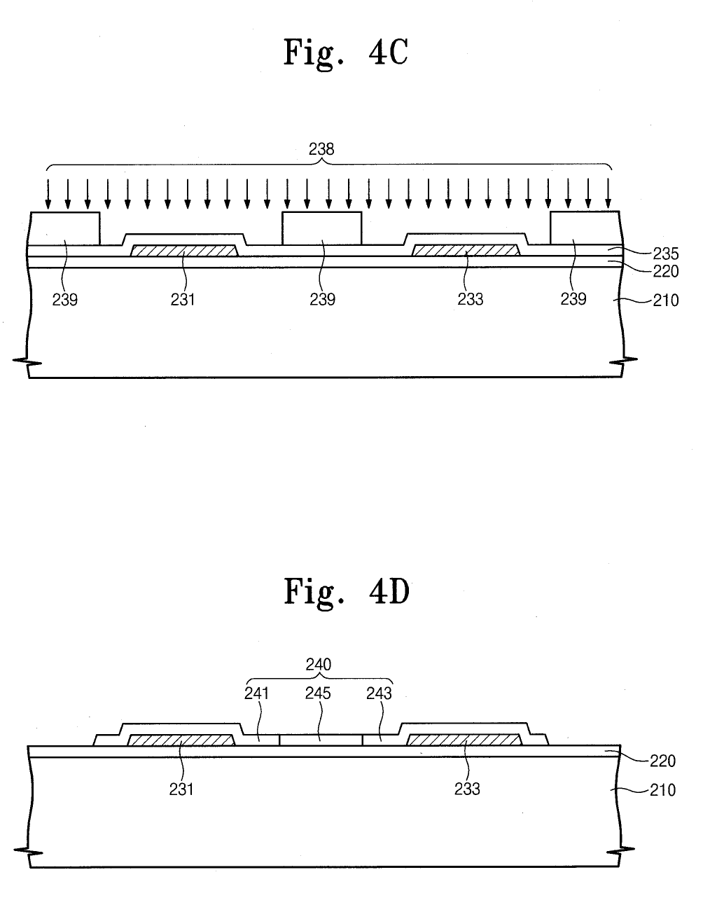

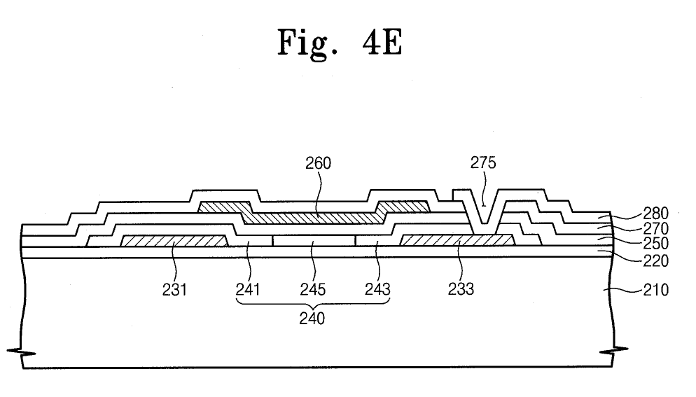

An exemplary method of manufacturing the display substrate according to one embodiment of the present invention will now be described with reference to FIGS. 3 and 4A to 4E. FIG. 3 is a flowchart diagram illustrating the method, and FIGS. 4A to 4E are cross sectional views showing the display substrate at different stages of fabrication according to the method of FIG. 3.

As shown at S10 in FIGS. 3, a buffer layer 220 (FIGS. 4A to 4E) is formed on a substrate 210. The buffer layer 220 includes an insulating layer.

Then, as shown in FIG. 4A, the source/drain metal is deposited on the buffer layer 220 and patterned to form source electrodes 231 and drain electrodes 233 (S11 in FIG. 3). In each pixel, the source electrode 231 and the drain electrode 233 are spaced from each other.

As shown in FIGS. 4B to 4D, a semiconductor layer 240 is formed in each pixel on the buffer layer 220, the source electrodes 231, and the drain electrodes 233 (S12) from a semiconductor material 235. In the present exemplary embodiment, the semiconductor material 235 may include microcrystalline silicon or amorphous silicon. If the microcrystalline silicon is used, it may be deposited by chemical vapor deposition to a thickness of about 50 angstroms to about 1000 angstroms. If the amorphous silicon is used, the amorphous silicon may be deposited and then crystallized by a laser crystallization method or a solid crystallization method.

Next, referring to FIG. 4C, photoresist (not shown) is formed on the semiconductor material 235 and patterned to form a photoresist pattern 239. Impurities 238, for example phosphorus (P) or boron (B), are implanted into those portions of the semiconductor material 235 which are not covered by the photoresist pattern 239. The implantation method can be ion implantation, e.g. ion shower.

After implanting the impurities 238 into the semiconductor layer 235, the photoresist pattern 239 is stripped and the semiconductor material 235 is patterned into the semiconductor layers 240 (FIG. 4D). The photoresist stripping and the patterning are not reflected in the drawings. One semiconductor layer 240 is provided in each pixel and includes a first ohmic contact region 241 overlaying upper and side surfaces of the source electrode 231, a second ohmic contact region 243 overlaying upper and side surfaces of the drain electrode 233, and a channel region 245 positioned between the first and second ohmic contact regions 241 and 243 and spaced from the source and drain electrodes 231 and 233.

After that, heat treatment or hydrogen plasma treatment is performed to improve properties of the first and second ohmic contact regions 241 and 243. For instance, the thermal anneal (i.e. the heat treatment) or hydrogen plasma treatment may heal defects in the crystal structure of the first and second ohmic contact regions 241 and 243 to provide stable crystalline structure.

Alternatively, to form the first ohmic contact region 241, the second ohmic contact region 243 and the channel region 245, the semiconductor material 235 may be patterned before doping. In this process, the semiconductor material 235 is deposited on the buffer layer 220, the source electrodes 231 and the drain electrodes 233 and etched to pattern the active areas containing the first ohmic contact regions 241, the second ohmic contact regions 243 and the channel regions 245. Then a photoresist pattern is formed on the semiconductor layer 235 to define the channel regions 245, and the impurities are implanted into the semiconductor layer 235 by ion implantation, possibly ion shower. As a result, the channel region 245 is formed in each pixel between the first and second ohmic contact regions 241 and 243 doped by the impurities.

Referring to FIG. 4E, an insulating layer 250 including an insulating material such as silicon oxide (SiOx) or silicon nitride (SiNx) is formed on the buffer layer 220 and the semiconductor layers 240 (S13). The insulating layer 250 may be formed in the same chamber (not shown) in which the semiconductor layers 240 were formed. That is, after forming the semiconductor layers 240, the insulating layer 250 may be formed by changing the gas composition in the chamber while the chamber is maintained at vacuum Accordingly, contamination or oxidation may be prevented at the interface between the semiconductor layers 240 and the insulating layer 250.

Next, a gate metal is formed on the insulating layer 250 and patterned to form gate electrodes 260 (S14). In each pixel, the gate electrode 260 overlies the channel region 245.

A protective layer 270 is formed on the insulating layer 250 and the gate electrodes 260. The protective layer 270 may include inorganic material such as silicon oxide (SiOx) or silicon nitride (SiNx), or organic material such as benzocyclobutene (BCB).

Then pixel electrodes 280 are formed on the protective layer 270 (S 16). In each pixel, the pixel electrode 280 is electrically connected to the drain electrode 233. More particularly, before forming the pixel electrodes 280, a contact hole 275 is etched in each pixel through the protective layer 270, the insulating layer 250 and the second ohmic contact region 243 to expose the drain electrode 233. Then, a transparent conductive material such as TO, ITO or IZO is deposited on the protective layer 270 and in the contact holes 275 and is patterned to form the pixel electrodes 280 each of which is electrically connected to the respective drain electrode 233 through the respective contact hole 275.

The above-described manufacturing method is tolerant to photolithographic misalignment which occurs in fabrication of the semiconductor layers 240. Indeed, the misalignment will not degrade the properties of the thin film transistors because there is a reliable contact between the first and second ohmic contact regions 241 and 243 on the one hand and the respective source and drain electrodes 231 and 233 on the other hand. In addition, since the semiconductor layers 240 and the insulating layer 250 may be successively formed in one chamber, the vacuum may be maintained during fabrication of the semiconductor layers 240 and the insulating layer 250, thereby preventing contamination and oxidation at the interface between the semiconductor layers 240 and the insulating layer 250.

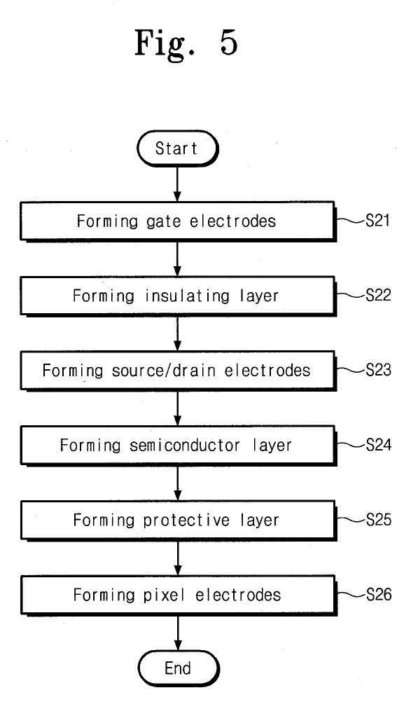

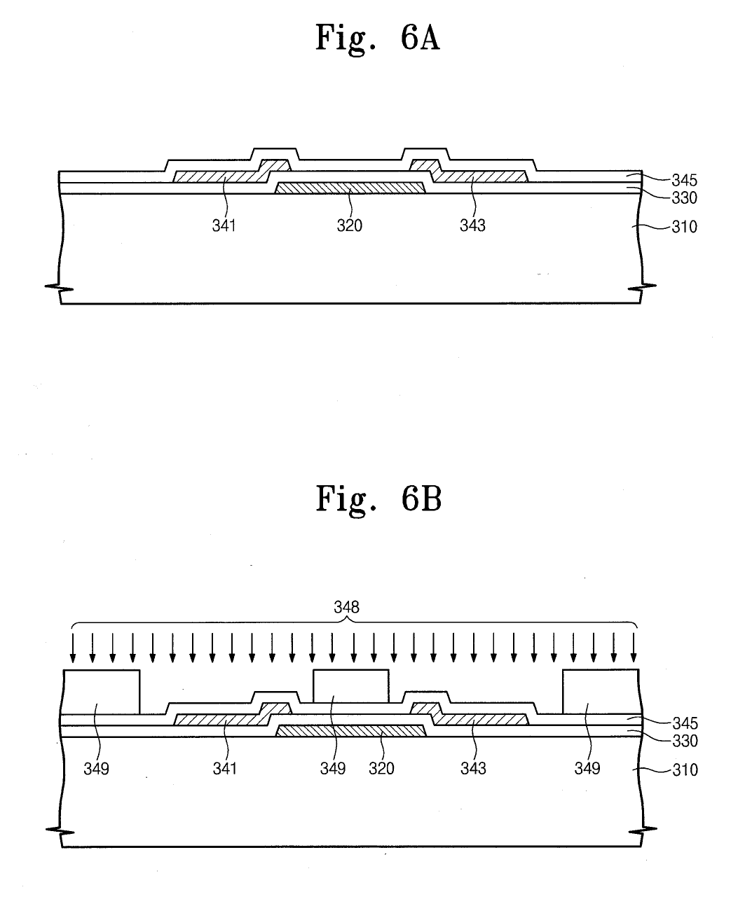

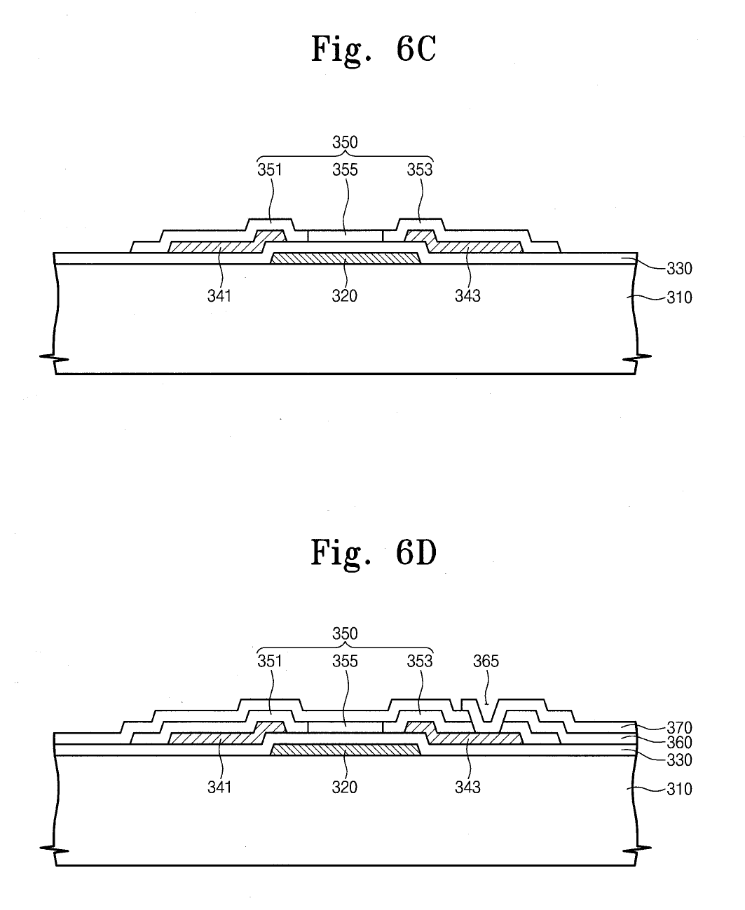

Another exemplary method of manufacturing the display substrate according to some embodiments of the present invention will now be described with reference to FIGS. 5 and 6A to 6D. FIG. 5 is a flowchart diagram illustrating the manufacturing method, and FIGS. 6A to 6D are cross sectional views showing the display substrate at different stages of fabrication according to FIG. 5. In FIGS. 5 and 6A to 6D, the same steps as those described above with reference with FIGS. 3 and 4A to 4E will not be described again to avoid redundancy.

As illustrated in FIGS. 5 and 6A to 6D, a gate metal is deposited on a substrate 310 and patterned to form gate electrodes 320 (S21). Then an insulating layer 330 is formed on the substrate 310 and the gate electrodes 320 (S22). A source/drain metal is formed on the insulating layer 330 and patterned to form source electrodes 341 and drain electrodes 343. The source electrode 341 and the drain electrode 343 are spaced from each other in each pixel (S23).

Next, as shown in FIGS. 6A to 6D, a semiconductor layer 350 is formed in each pixel on the insulating layer 330, the source electrodes 341 and the drain electrodes 343 (S24). More particularly, as shown in FIG. 6A, a semiconductor material 345 is deposited on the insulating layer 330, the source electrodes 341 and the drain electrodes 343 by chemical vapor deposition. The semiconductor material 345 may include microcrystalline silicon or amorphous silicon. As shown in FIG. 6B, photoresist is deposited on the semiconductor material 345 and patterned to form a photoresist pattern 349. After that, impurities such as phosphorus (P), boron (B), or the like are implanted into those portions of the semiconductor material 345 which are not covered by the photoresist pattern 349. The impurities can be implanted by ion implantation, e.g. ion shower.

After implanting the impurities 348 into the semiconductor material 345, the photoresist pattern 349 is stripped and the semiconductor material 345 is patterned (these steps are not reflected in the drawings).

As a result, a semiconductor layer 350 (FIG. 6C) is formed in each pixel and includes, in each pixel, a first ohmic contact region 351 that overlays upper and side surfaces of the source electrode 341, a second ohmic contact region 353 that overlays upper and side surfaces of the drain electrode 343, and a channel region 355 positioned between the first and second ohmic contact regions 351 and 353 and spaced from the source and drain electrodes 341 and 343.

After that, heat treatment or hydrogen plasma treatment is performed to improve properties of the first and second ohmic contact regions 351 and 353.

Alternatively, to form the first ohmic contact region 351, the second ohmic contact region 353 and the channel region 355, the semiconductor material 345 may be patterned before doping.

When the semiconductor layers 350 have been formed, a protective layer 360 is formed on the insulating layer 330 and the semiconductor layers 350 (S25), and a pixel electrode 370 is formed in each pixel on the protective layer 360 in electrical contact with the corresponding drain electrode 343 (S26). In each pixel, the pixel electrode 370 is electrically connected to the drain electrode 343 through a contact hole 365 formed through the protective layer 360 and the second ohmic contact region 353.

The above-described manufacturing method is tolerant to photolithographic misalignment which occurs in fabrication of the semiconductor layers 350. Indeed, the misalignment will not degrade properties of the thin film transistors. In addition, since the semiconductor layers 350 and the protective layer 360 may be successively formed in one chamber, the vacuum may be maintained during fabrication of the semiconductor layers 350 and the protective layer 360, thereby preventing contamination and oxidation at the interface between the semiconductor layers 350 and the protective layer 360.

In some embodiments described above, the ohmic contact regions overlay the source and drain electrodes in top-gate and bottom-gate structures. The channel region is spaced from the source and drain electrodes, thereby reducing current leakage.

In addition, since layers may be successively formed in a single chamber above the semiconductor layers, the interfaces between the layers and the features may be improved.

The present invention is not limited to the embodiments described above but includes other embodiments and variations as defined by the appended claims.

What is claimed is:

1. A display substrate comprising:
a substrate;
a source electrode arranged on the substrate;
a drain electrode arranged on the substrate and spaced from the source electrode;
a semiconductor layer arranged on the source electrode and the drain electrode;
an insulating layer arranged on the semiconductor layer; and
a gate electrode arranged on the insulating layer,
wherein the semiconductor layer comprises:
a first ohmic contact region that overlays an upper surface and a side surface of the source electrode;
a second ohmic contact region that overlays an upper surface and a side surface of the drain electrode; and
a channel region that is spaced from the source and drain electrodes and interconnects the first ohmic contact region and the second ohmic contact region.

2. The display substrate of claim 1, wherein the channel region is arranged on the substrate's portion not covered by the first and second ohmic contact regions.

3. The display substrate of claim 1, wherein peripheral areas of the first ohmic contact region cover areas of the substrate adjacent to the source electrode, and peripheral areas of the second ohmic contact region cover areas of the substrate adjacent to the drain electrode.

4. The display substrate of claim 1, wherein the semiconductor layer comprises at least one of microcrystalline silicon, amorphous silicon and polysilicon.

5. The display substrate of claim 1, further comprising a buffer layer arranged under the source electrode, the drain electrode and the semiconductor layer.

6. A display substrate comprising:
a substrate;
a gate electrode arranged on the substrate;
an insulating layer arranged on the substrate over the gate electrode;
a source electrode arranged on the insulating layer;
a drain electrode arranged on the insulating layer and spaced from the source electrode; and
a semiconductor layer arranged on the source electrode and the drain electrode,
wherein the semiconductor layer comprises:
a first ohmic contact region that overlays an upper surface and a side surface of the source electrode;
a second ohmic contact region that overlays an upper surface and a side surface of the drain electrode; and
a channel region that is spaced from the source and drain electrodes and interconnects the first ohmic contact region and the second ohmic contact region.

7. The display substrate of claim 6, wherein the channel region is arranged on the substrate's portion not covered by the first and second ohmic contact regions.

8. The display substrate of claim 6, wherein peripheral areas of the first ohmic contact region cover areas of the substrate adjacent to the source electrode, and peripheral areas of the second ohmic contact region cover areas of the substrate adjacent to the drain electrode.

9. The display substrate of claim 6, wherein the semiconductor layer comprises at least one of microcrystalline silicon, amorphous silicon and polysilicon.

10. A method of manufacturing a display substrate, the method comprising:
forming, on a substrate, a source electrode and a drain electrode spaced from the source electrode;
depositing a semiconductor material on the substrate, the source electrode and the drain electrode to form a semiconductor layer including a first ohmic contact region that overlays an upper surface and a side surface of the source electrode, a second ohmic contact region that overlays an upper surface and a side surface of the drain electrode, and a channel region that is spaced from the source and drain electrodes and overlays the substrate's portion between the first ohmic contact region and the second ohmic contact region;
forming an insulating layer on the semiconductor layer;
forming a gate electrode on the insulating layer; and
forming a protective layer on the gate electrode and the insulating layer.

11. The method of claim 10, wherein forming the semiconductor material to form the semiconductor layer comprises:
depositing the semiconductor material on the substrate, the source electrode and the drain electrode;
doping the semiconductor material to define the first ohmic contact region, the second ohmic contact region and the channel region; and
removing the semiconductor material from areas which do not contain the first ohmic contact region, the second ohmic contact region and the channel region.

12. The method of claim 11, wherein the doping of the semiconductor material is performed by ion implantation.

13. The method of claim 10, wherein forming the semiconductor material to form the semiconductor layer comprises:
depositing the semiconductor material on the substrate, the source electrode and the drain electrode;
etching the semiconductor material to form the semiconductor layer that overlays upper and side surfaces of each of the source and drain electrodes and overlays the substrate between the source electrode and the drain electrode; and
doping the semiconductor layer to define the first ohmic contact region, the second ohmic contact region and the channel region.

14. The method of claim 13, wherein the doping of the semiconductor layer is performed by ion implantation.

15. The method of claim 10, wherein the semiconductor material is deposited by chemical vapor deposition, and the semiconductor material comprises at least one of microcrystalline silicon and amorphous silicon.

16. The method of claim 10, further comprising, after forming the protective layer:
etching the protective layer and the insulating layer to form a contact hole that partially exposes the drain electrode; and
forming a pixel electrode electrically connected to the drain electrode through the contact hole.

17. The method of claim 10, further comprising forming a buffer layer on the substrate prior to forming the source and drain electrodes.

18. A method of manufacturing a display substrate, the method comprising:
forming a gate electrode on a substrate;
forming an insulating layer on the substrate over the gate electrode;
forming, on the insulating layer, a source electrode and a drain electrode spaced from the source electrode;
forming a semiconductor layer on the insulating layer, the source electrode and the drain electrode, the semiconductor layer including a first ohmic contact region that overlays an upper surface and a side surface of the source electrode, a second ohmic contact region that overlays an upper surface and a side surface of the drain electrode, and a channel region that is spaced from the source and drain electrodes and overlays the substrate's portion between the first ohmic contact region and the second ohmic contact region; and
forming a protective layer on the semiconductor layer.

19. The method of claim 18, wherein forming the semiconductor layer comprises:
depositing a semiconductor material on the insulating layer, the source electrode and the drain electrode;
doping the semiconductor material to define the first ohmic contact region, the second ohmic contact region, and the channel region; and
removing the semiconductor material from areas which do not contain the first ohmic contact region, the second ohmic contact region and the channel region.

20. The method of claim 19, wherein the doping of the semiconductor material is performed by ion implantation method.

21. The method of claim 18, wherein forming the semiconductor layer comprises:
depositing a semiconductor material on the insulating layer, the source electrode and the drain electrode;
etching the semiconductor material to form the semiconductor layer that overlays upper surfaces and side surfaces of the source and drain electrodes; and
doping the semiconductor layer to define the first ohmic contact region, the second ohmic contact region and the channel region.

22. The method of claim 21, wherein the doping of the semiconductor layer is performed by ion implantation.

23. The method of claim 18, wherein the semiconductor layer is deposited by chemical vapor deposition and comprises at least one of microcrystalline silicon and amorphous silicon.
